(19) United States
(12) Patent Application Publication
(10) Pub. No.: US 2023/0010901 A1
(43) Pub. Date: Jan. 12, 2023

(54) SEMICONDUCTOR DEVICE HAVING PLURAL CELL CAPACITORS EMBEDDED IN EMBEDDING MATERIAL

(71) Applicant: Micron Technology, Inc., Boise, ID (US)

(72) Inventors: Yosuke Adachi, Hiroshima-shi (JP); Hiroshi Amaike, Higashihiroshima (JP); Keisuke Otsuka, Kasaoka (JP); Shogo Omiya, Higashihiroshima (JP); Tomohiro Iwaki, Higashihiroshima (JP); Emi Seko, Higashihiroshima (JP)

(73) Assignee: Micron Technology, Inc., Boise, ID (US)

(21) Appl. No.: 17/372,397

(22) Filed: Jul. 9, 2021

(51) Int. Cl. H01L 27/108

(52) U.S. Cl. CPC H01L 27/10808; H01L 27/10897; H01L 27/10855

(57) ABSTRACT

Disclosed herein is an apparatus that includes a plurality of cell capacitors arranged in a memory cell array region of a semiconductor substrate, each of the plurality of cell capacitors having a first electrode, a second electrode and an insulating film therebetween to electrically disconnect the first and second electrodes, a first conductive member including the plurality of cell capacitors therein, the first conductive member being electrically connected in common to the first electrodes of the plurality of cell capacitors, and a second conductive member formed on an upper surface of the first conductive member, a material of the second conductive member being different from that of the first conductive member. A side surface of the first conductive member is free from the second conductive member.

### BACKGROUND

A memory device such as a DRAM (Dynamic Random Access Memory) includes a memory cell array region in which a plurality of cell capacitors are regularly arrayed, and a peripheral circuit region in which peripheral circuits such as a sense amplifier and a word driver are arranged. The plurality of cell capacitors are embedded in an embedding material including a conductive material. A side surface of the embedding material is located near the boundary between the memory cell array region and the peripheral circuit region. Therefore, if the side surface of the embedding material is close to the peripheral circuit region, a margin between contact plugs provided in the peripheral circuit region and the embedding material is decreased.

### BRIEF DESCRIPTION OF THE DRAWINGS

FIG. 1A is a schematic sectional view for explaining a structure of a semiconductor device according to a first embodiment of the present disclosure;

FIG. 1B is a schematic diagram of a cell capacitor,

FIG. 2A to FIG. 2F are schematic sectional views each showing a step of manufacturing process of the semiconductor device according to the first embodiment;

FIG. 3 is a schematic sectional view for explaining a structure of a semiconductor device according to a second embodiment of the present disclosure; and

FIG. 4A to FIG. 4D are schematic sectional views each showing a step of manufacturing process of the semiconductor device according to the second embodiment.

### DETAILED DESCRIPTION

Various embodiments of the present invention will be explained below in detail with reference to the accompanying drawings. The following detailed description refers to the accompanying drawings that show, by way of illustration, specific aspects, and embodiments in which the present invention may be practiced. These embodiments are described in sufficient detail to enable those skilled in the art to practice the present invention. Other embodiments may be utilized, and structural, logical, and electrical changes may be made without departing from the scope of the present invention. The various embodiments disclosed herein are not necessary mutually exclusive, as some disclosed embodiments can be combined with one or more other disclosed embodiments to form new embodiments.

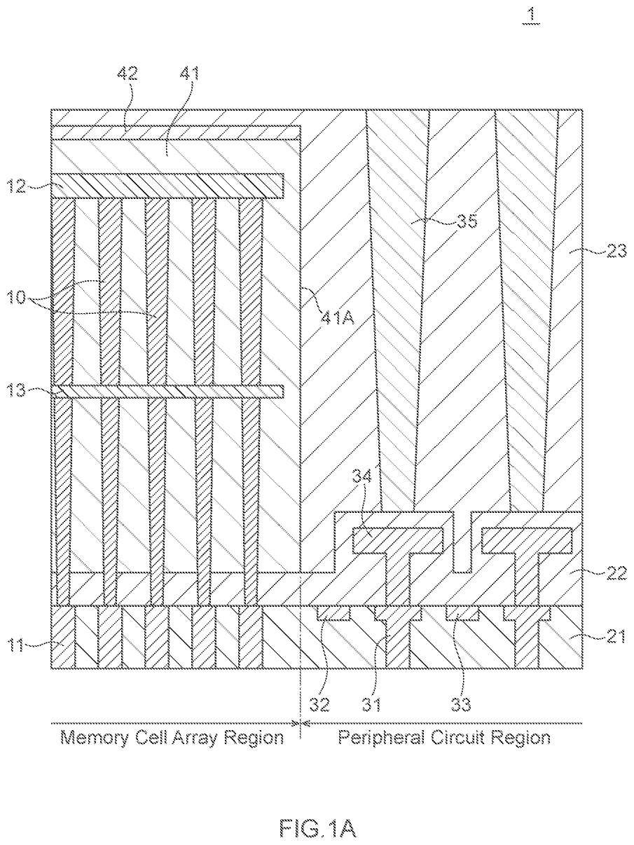

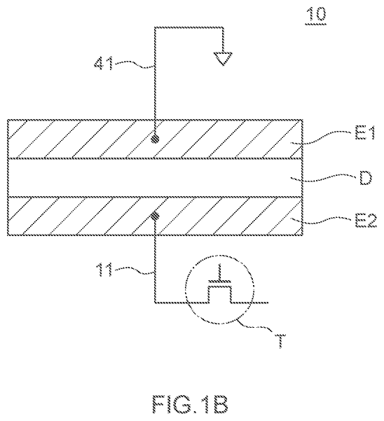

FIG. 1A is a schematic sectional view for explaining a structure of a semiconductor device according to a first embodiment of the present disclosure. A semiconductor device 1 according to the first embodiment is a DRAM and the semiconductor device 1 includes a memory cell array region in which a plurality of cell capacitors 10 are regularly arrayed, and a peripheral circuit region in which peripheral circuits (not shown) such as a sense amplifier and a word driver are arranged as shown in FIG. 1A. Each of the cell capacitors 10 includes a pair of capacitor electrodes E1 and E2, and a capacitor dielectric film D located therebetween as shown in FIG. 18. The capacitor electrode E2 (second electrode) is connected to a cell transistor T via a cell contact plug 11 provided to penetrate through an interlayer dielectric film 21 and the capacitor electrode E1 (first electrode) is electrically connected to an embedding material 41 (first conductive member) including a conductive material such as polycrystalline silicon. The cell capacitors 10 are configured to be embedded in the embedding material 41. The upper surface of the embedding material 41 is covered with a conductive film 42 (second conductive member) including tungsten and the like. Plate potentials of the cell capacitors 10 are supplied to the embedding material 41 via the conductive film 42. Upper parts of the cell capacitors 10 are supported by an insulating film 12 functioning as abeam. Substantially central parts in the height direction of the cell capacitors 10 are supported by another insulating film 13 functioning as a beam. The insulating films 12 and 13 project toward the peripheral circuit region from ones of the cell capacitors 10 located at an end of the memory cell array region.

Referring back to FIG. 1A, contact plugs 31, wiring patterns 32 and 33, and the like embedded in the interlayer dielectric film 21 are provided in the peripheral circuit region. The contact plugs 31 and the wiring patterns 32 and 33 are covered with an interlayer dielectric film 22. An interlayer dielectric film 23 is provided on the interlayer dielectric film 22. The interlayer dielectric film 23 is a film having a sufficient thickness and this eliminates a difference in the level between the memory cell array region and the peripheral circuit region. Contact plugs 35 penetrating through the interlayer dielectric film 23 are provided in the peripheral circuit region. Since the embedding material 41 includes a conductive material, a predetermined margin is required between ones of the contact plugs 35 located at the end and the embedding material 41 to prevent short-circuiting therebetween.

As shown in FIG. 1A, a side surface 41A of the embedding material 41 is substantially perpendicular to the principal surface of a semiconductor substrate and has a high flatness. The side surface 41A of the embedding material 41 is not covered with the conductive film 42 and is in contact with the interlayer dielectric film 23.

A manufacturing process of the semiconductor device 1 according to the present embodiment is explained next.

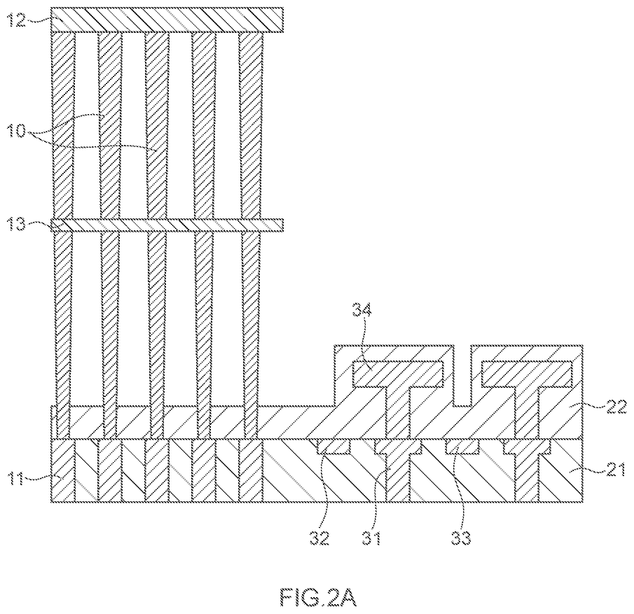

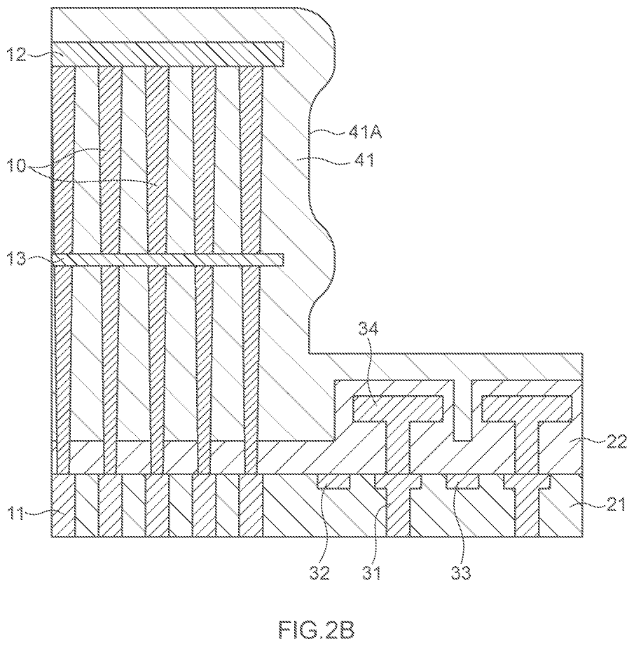

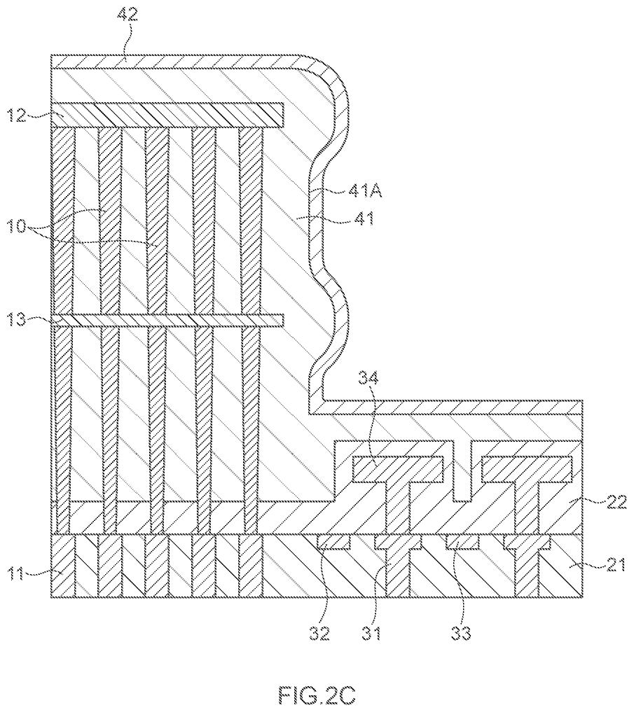

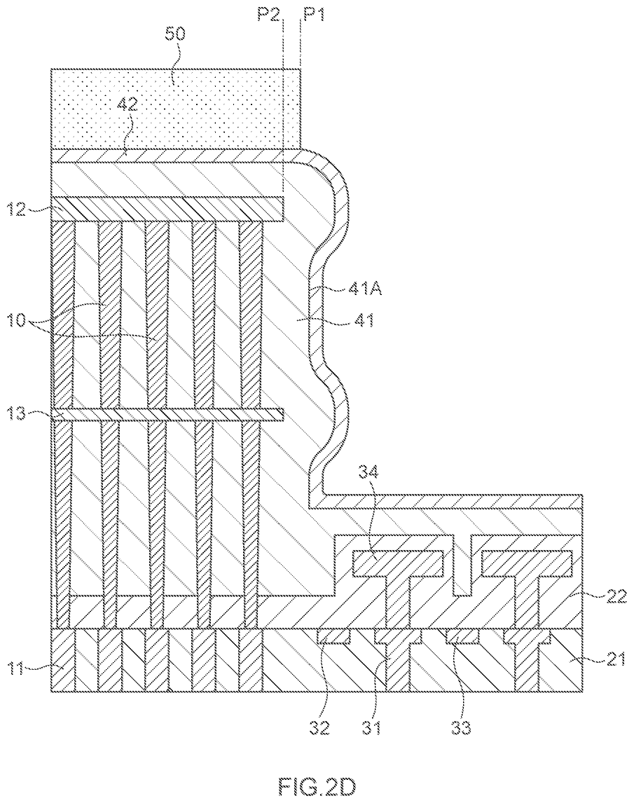

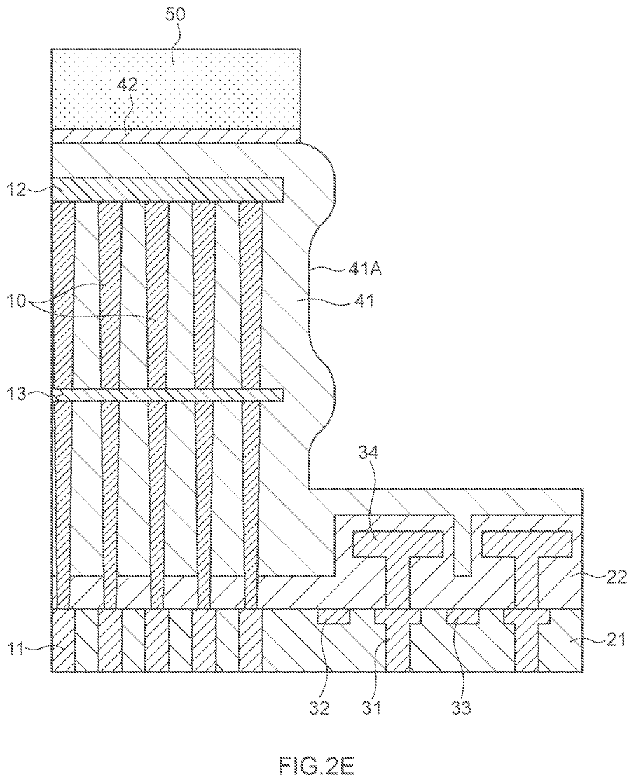

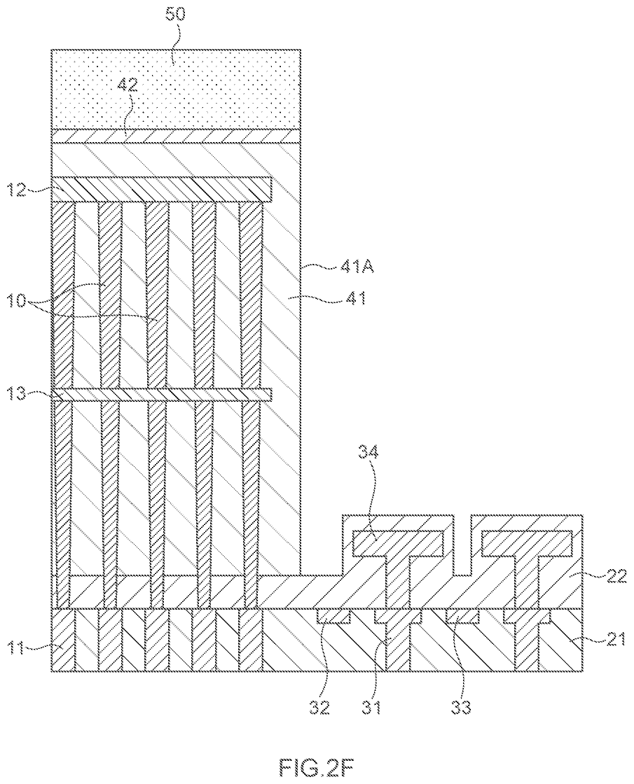

First, the contact plugs 31, the wiring patterns 32 and 33, and the like are formed in the peripheral circuit region as shown in FIG. 2A. Next, the contact plugs 31 and the wiring patterns 32 and 33 are covered with the interlayer dielectric film 22 and a plurality of the cell capacitors 10 are subsequently formed in the memory cell array region. Next, as shown in FIG. 2B, the embedding material 41 including polycrystalline silicon and the like is formed all over to embed the cell capacitors 10 in the embedding material 41. As a result, a large difference in the level is produced between the memory cell army region and the peripheral circuit region. Since the ends of the insulating films 12 and 13 project toward the peripheral circuit region, bulges are produced on the side surface 41A of the embedding material 41 at same height locations as those of the insulating films 12 and 13. That is, the side surface 41A is not flat and has irregularities in a state immediately after the embedding material 41 is formed.

Next, the conductive film 42 including tungsten and the like is formed all over as shown in FIG. 2C. Subsequently, a mask 50 is formed on the upper surface of the conductive film 42 by a photolithography method as shown in FIG. 2D. At that time, an edge location P1 of the mask 50 is adjusted so as not to cover the side surface of the conductive film 42 with the mask 50. However, it is preferable that the edge location P1 of the mask 50 be located on the side of the peripheral circuit region relative to an edge location P2 of the insulating films 12 and 13. A non-biased isotropic dry etching is performed in this state, whereby a part of the conductive film 42 not covered with the mask 50 is removed as shown in FIG. 2E. Accordingly, the conductive film 42 on the peripheral circuit region is all removed and the conductive film 42 on the side surface 41A of the embedding material 41 is removed to expose the side surface 41A of the embedding material 41. Next, an anisotropic dry etching where the bias is adjusted is performed to remove the surface layer of the side surface 41A of the embedding material 41 as shown in FIG. 2F. In this anisotropic dry etching, the bias is adjusted to cause the etching rate in the vertical direction to be sufficiently higher than the etching rate in the horizontal direction. Accordingly, the irregularities on the side surface 41A of the embedding material 41 are removed to substantially flatten the side surface 41A and the planar location of the side surface 41A is set back toward the memory cell array region. With subsequent formation of the interlayer dielectric film 23 and the contact plugs 35, the structure shown in FIG. 1A is obtained.

As described above, in the present embodiment, after the embedding material 41 and the conductive film 42 are formed, the conductive film 42 is isotropically etched to expose the side surface 41A of the embedding material 41, and the embedding material 41 is further anisotropically etched to slim the embedding material 41. Therefore, the margin between ones of the contact plugs 35 located at the end and the embedding material 41 is enlarged. Therefore, the chip size can be reduced using this margin. Furthermore, since the side surface 41A of the embedding material 41 is flattened, seams are less likely to be formed in the interlayer dielectric film 23 and defects in the contact plugs 35 resulting from seams can be prevented.

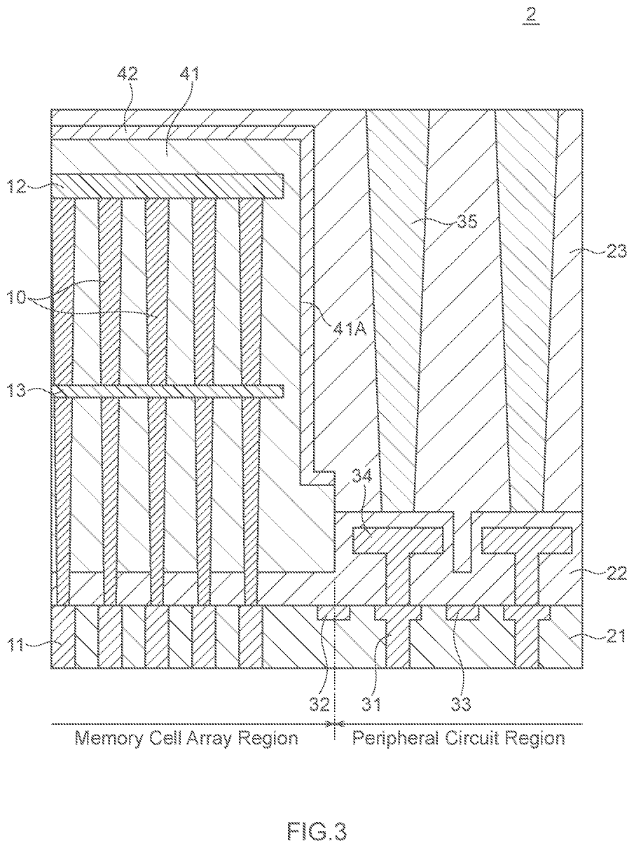

FIG. 3 is a schematic sectional view for explaining a structure of a semiconductor device according to a second embodiment of the present disclosure. As shown in FIG. 3, a semiconductor device 2 according to the second embodiment is different from the semiconductor device 1 shown in FIG. 1A in that the side surface 41A of the embedding material 41 is covered with the conductive film 42 and that a part of the embedding material 41 remains in the peripheral circuit region. Since the rest of the basic configuration thereof is same as that of the semiconductor device 1 shown in FIG. 1A, same elements are denoted by like reference numerals and redundant explanations thereof are omitted.

A manufacturing process of the semiconductor device 2 according to the present embodiment is explained below.

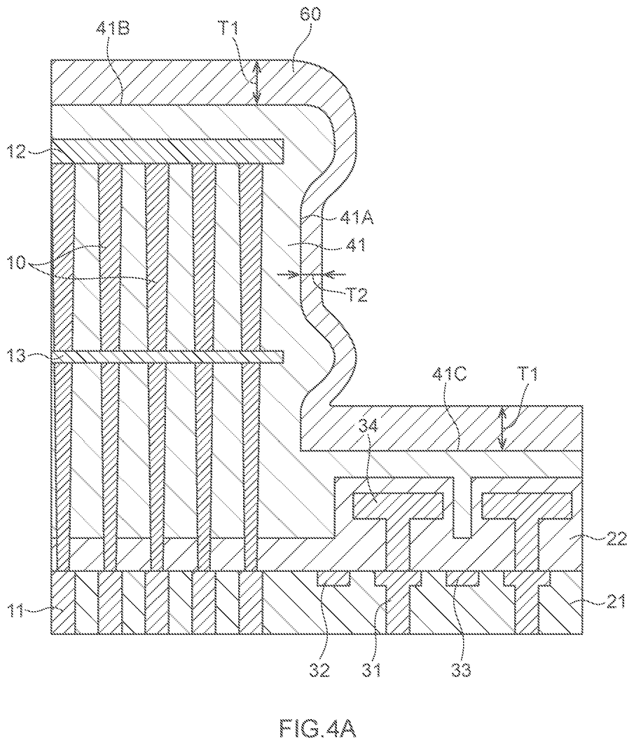

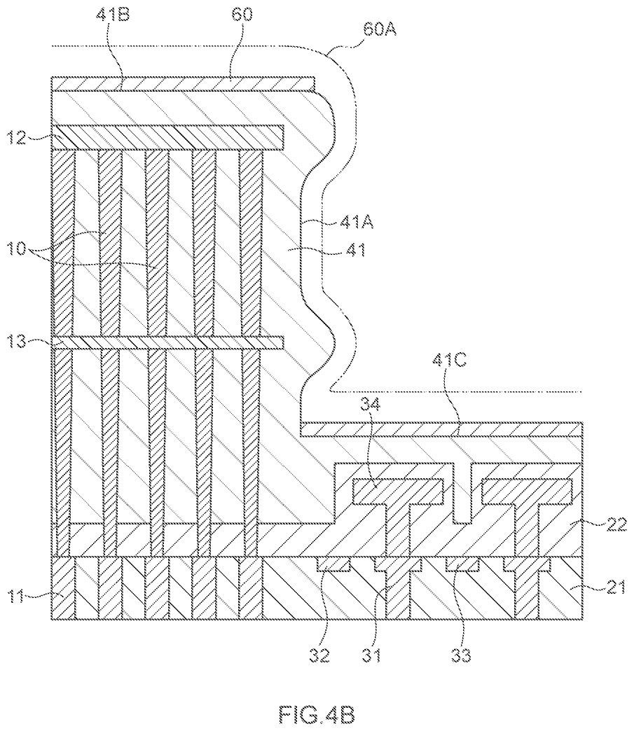

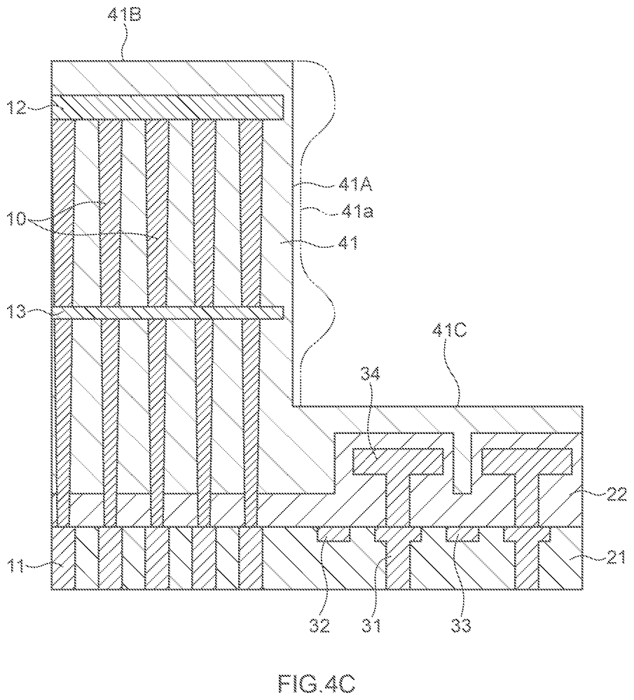

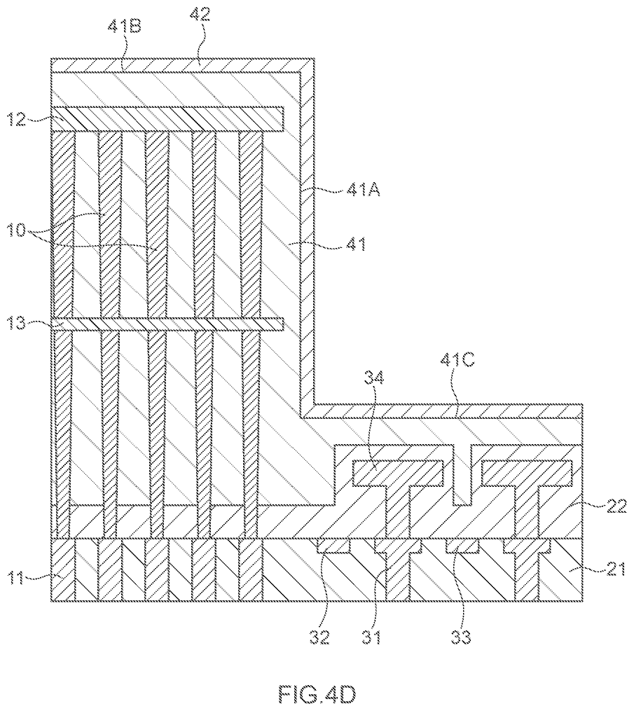

First, after the processes explained with reference to FIGS. 2A and 2B are performed, a mask film 60 including silicon oxide and the like is formed all over as shown in FIG. 4A. The mask film 60 is formed in a condition where the film thickness on a face horizontal to the principal surface of the semiconductor substrate becomes thicker than a film thickness on a face perpendicular to the principal surface of the semiconductor substrate. Accordingly, a film thickness T1 of the mask film 60 formed on an upper surface 41B of the embedding material 41 in the memory cell array region and an upper surface 41C of the embedding material 41 in the peripheral circuit region is thicker than a film thickness T2 of the mask film 60 formed on the side surface 41A of the embedding material 41. Next, as shown in FIG. 413, the mask film 60 is wet etched to remove a part thereof formed on the side surface 41A of the embedding material 41 and expose the side surface 41A of the embedding material 41. At that time, the etching amount needs to be adjusted to cause the mask film 60 formed on the upper surface 41B of the embedding material 41 to remain. Reference numeral 60A shown in FIG. 4B denotes a surface location of the mask film 60 immediately after formation. An anisotropic dry etching is performed using the mask film 60 in this state as a mask, whereby the surface layer of the side surface 41A of the embedding material 41 is removed as shown in FIG. 4C. In this anisotropic dry etching, the bias adjustment is performed to cause the etching rate in the vertical direction to be sufficiently higher than the etching rate in the horizontal direction. Accordingly, irregularities on the side surface 41A of the embedding material 41 are removed to substantially flatten the side surface 41A and the planar location of the side surface 41A is set back toward the memory cell array region. Reference numeral 41a shown in FIG. 4C denotes a surface location of the embedding material 41 immediately after formation. The mask film 60 is subsequently removed.

Next, the conductive film 42 including tungsten and the like is formed all over as shown in FIG. 4D. The conductive film 42 and the embedding material 41 formed in the peripheral circuit region are removed by an etching and the interlayer dielectric film 23 and the contact plugs 35 are subsequently formed, whereby the structure shown in FIG. 3 is obtained.

As described above, since the embedding material 41 is slimmed also in the present embodiment, the margin between ones of the contact plugs 35 located at the end and the embedding material 41 is enlarged. Therefore, the chip size can be reduced using this margin. Further, since the side surface 41A of the embedding material 41 is flattened, seams are less likely to be formed in the interlayer dielectric film 23 and defects in the contact plugs 35 resulting from seams can be prevented.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a plurality of cell capacitors arranged in a memory cell array region of a semiconductor substrate, each of the plurality of cell capacitors having a first electrode, a second electrode and an insulating film therebetween to electrically disconnect the first and second electrodes;
a first conductive member including the plurality of cell capacitors therein, the first conductive member being electrically connected in common to the first electrodes of the plurality of cell capacitors; and
a second conductive member formed on an upper surface of the first conductive member, a material of the second conductive member being different from that of the first conductive member,
wherein a side surface of the first conductive member is free from the second conductive member.

2. The apparatus of claim 1, further comprising an insulating member covering the second conductive member and the side surface of the first conductive member.

3. The apparatus of claim 2, further comprising:
a wiring pattern formed in a peripheral circuit region of the semiconductor substrate adjacent to the cell array region; and
a contact plug electrically connected to the wiring pattern so as to penetrate the insulating member.

4. The apparatus of claim 1, wherein the first conductive member comprises polycrystalline silicon.

5. The apparatus of claim 1, wherein the second conductive member comprises tungsten.

6. The apparatus of claim 1, wherein the side surface of the first conductive member is substantially flat.

7. The apparatus of claim 6, further comprising a beam insulating film extending in a direction substantially parallel to the semiconductor substrate to support the plurality of cell capacitors extending in a direction substantially perpendicular to the semiconductor substrate,
wherein the beam insulating film projects toward the side surface of the first conductive member from ones of the cell capacitors located at an end of the memory cell array region.

8. A method comprising:
forming a plurality of cell capacitors in a memory cell array region of a semiconductor substrate, each of the plurality of cell capacitors having a first electrode, a second electrode and an insulating film therebetween to electrically disconnect the first and second electrodes:
forming a first conductive member to include the plurality of cell capacitors therein such that the first conductive member is electrically connected in common to the first electrodes of the plurality of cell capacitors;
forming a second conductive member comprising different material from the first conductive member on upper and side surfaces of the first conductive member,
forming a mask on an upper surface of the second conductive member without covering a side surface of the second conductive member,
removing a part of the second conductive member formed on the side surface of the first conductive member by using the mask to expose the side surface of the first conductive member; and
removing a surface layer of the side surface of the first conductive member by using the mask.

9. The method of claim 8, wherein the removing the second conductive member is performed by an isotropic etching.

10. The method of claim 9, wherein the removing the first conductive member is performed by an anisotropic etching.

11. The method of claim 10, wherein the removing the first conductive member is performed until the first conductive member formed on a peripheral circuit region of the semiconductor substrate adjacent to the cell array region is removed.

12. The method of claim 8,
wherein the first conductive member comprises polycrystalline silicon, and
wherein the second conductive member comprises tungsten.

13. A method comprising:
forming a plurality of cell capacitors in a memory cell array region of a semiconductor substrate, each of the plurality of cell capacitors having a first electrode, a second electrode and an insulating film therebetween to electrically disconnect the first and second electrodes;
forming a first conductive member to include the plurality of cell capacitors therein such that the first conductive member is electrically connected in common to the first electrodes of the plurality of cell capacitors;
forming a mask film on upper and side surfaces of the first conductive member,
removing a part of the mask film formed on the side surface of the first conductive member to expose the side surface of the first conductive member; and
removing a surface layer of the side surface of the first conductive member by using the mask film.

14. The method of claim 13, further comprising forming, after removing the surface layer, a second conductive member comprising different material from the first conductive member on the upper and side surfaces of the first conductive member.

15. The method of claim 14, further comprising removing the first and second conductive members formed on a peripheral circuit region of the semiconductor substrate adjacent to the cell array region.

16. The method of claim 15,
wherein the first conductive member comprises polycrystalline silicon, and
wherein the second conductive member comprises tungsten.

17. The method of claim 13, wherein the forming the mask film is performed such that a thickness of the mask film on the upper surface of the first conductive member is thicker than a thickness of the mask film on the side surface of the first conductive member.

18. The method of claim 17, wherein the removing the mask film is performed by an isotropic etching.

19. The method of claim 18, wherein the removing the mask film is performed by a wet etching.

20. The method of claim 19, wherein the removing the surface layer is performed by a dry etching.
